(19) United States
(12) Patent Application Publication
(10) Pub. No.: US 2004/0177300 A1
(43) Pub. Date: Sep. 9, 2004

(54) Apparatus with a test interface

(76) Inventors: Alexander Sebastian Biewenga, Eindhoven (NL); Thomas Franciscus Waayers, Eindhoven (NL)

Correspondence Address: PHILIPS ELECTRONICS NORTH AMERICA CORPORATION, INTELLECTUAL PROPERTY & STANDARDS, 1109 MCKAY DRIVE, M/S-41SJ, SAN JOSE, CA, 95131, US

(21) Appl. No.: 10/482,015

(22) PCT Filed: Jun. 20, 2002
(86) PCT No.: PCT/IB02/02443

(30) Foreign Application Priority Data
Jul. 5, 2001 (EP) 01202594.6

(51) Int. Cl. G01R 31/28

(52) U.S. Cl. 714/727

(57) ABSTRACT

Boundary scan test circuits are controlled by a test state machine capable of assuming respective test states successively in successive test clock cycles. A single input of the test signal is normally used to control selection of successive states assumed by the test state machine. The test state machine has a standard state diagram of possible states. Further the test circuit contains a shift register to transport test data. A co-processor state machine is provided, capable of assuming respective co-processor states successively in successive cycles of the test clock. The co-processor state machine, when enabled, starts making transitions from a start state in response to assumption of a predetermined one of the test states by the test state machine. The co-processor states assumed by the co-processor following the start state control successive steps of an operation that uses data output from the scan chain under control of the test state machine and/or produce results read into the scan chain under control of the test state machine following the predetermined state. In an embodiment the co-processor supplies successive control signals to program a non-volatile memory in respective ones of the co-processor states. Programmed data is read from the scan chain in test clock cycles determined by the co-processor state machine.

The invention relates to an apparatus with a test interface, and in particular to the use of such an apparatus to perform operations like programming a non-volatile memory.

European Patent Application No. EP 0981134 discloses a signal processing apparatus with a CPU (Central Processing Unit, i.e. a unit capable of executing programmed instructions) that controls writing (programming) of information into a non-volatile memory via a scan chain. The information is for example a computer program to control the apparatus during its normal use. Such programs need to be loaded only rarely, for example during manufacturing or servicing of the apparatus.

As described in this publication the program for writing the information and the information itself is fed to a CPU via a scan chain that is normally used for test purposes. An example of such a scan chain is specified in the 1149.1 standard of the IEEE (JTAG standard). The JTAG standard provides for a test unit with a minimum number of external pins, a shift register to transport test data from the pins through an apparatus and a so-called TAP controller. The TAP controller acts as a test state machine to control the mode of operation of the test circuit. One of the pins selects which successive test states this test state machine assumes. In each state the test state machine outputs state specific signals to control whether the data is transported through the shift register, output to perform a test or input to observe the result of a test etc.

From U.S. Pat. No. 5,978,945 an arrangement for testing a DRAM memory is known. In this arrangement data and addressed are supplied via the scan chain. A logic circuitry generates a RAS/CAS transition triggered by a predetermined state of the test state machine. Programming of non-volatile memory, such as flash memory is considerably more complicated than writing data to a DRAM. It generally involves application of a series of control patterns to the flash memory. It is known to program data into flash memory from a standard scan chain. For this purpose all necessary controlling signal patterns for programming the non-volatile memory are loaded into the scan chain, together with the information that has to be stored in the memory.

By using the standard scan chain to program the information into the non-volatile memory the information can be programmed when the non-volatile memory has already been mounted on-board the apparatus and interconnected with other components of the apparatus. Moreover, no special interface is needed to do so, because the standard test interface is used. This technique, however, is very time consuming, because a lot of signals are needed to program non-volatile memories and all these signals have to be transported through the scan chain.

The apparatus according to EP 0981134 uses a CPU to generate most of these signals to program the non-volatile memory. A program for programming the non-volatile memory and the information that has to be programmed are loaded into a temporary memory from the scan chain. Under control of the program the CPU writes the information from the temporary memory into the non-volatile memory. The program causes the CPU to provide signals to the memory in a number of clock cycles to control programming. In an example of a flash memory programming involves repeated cycles in which predetermined combinations of data and address are applied to the memory, followed by a cycle in which the address of the location that is to be programmed and the data that is to be programmed are applied. This in turn is followed by polling cycles to wait until programming is completed.

More generally, the CPU could be used to perform other operations than programming non-volatile memories using the information from the scan chain as well. The use of a CPU involves no additional cost if such a CPU is available in the apparatus and is in a position to perform the operations, for example if it has the necessary connections to the non-volatile memory. However, if no CPU is normally used in the apparatus, or if it does not have the necessary connections, for example because the non-volatile memory is localized in such a way that the CPU does not normally have the necessary access to program the memory in the apparatus, use of this technique with a CPU would involve considerable modification of the apparatus, with associated cost, to execute such operations.

Amongst others, it is an object of the invention to provide for an apparatus in which operations that use information from the scan chain and/or deliver information to the scan chain can be performed at high speed without using a central processing unit.

Amongst others, it is a further object of the invention to provide for an apparatus in which programming of a non-volatile memory using data from the scan chain can be performed at high speed without using a central processing unit.

The apparatus according to the invention, which may be an integrated circuit or a set containing a number of integrated circuits is set forth in claim 1. According to the invention, an additional state machine is included in the apparatus which acts as a co-processor state machine. Each time it is started the co-processor state machine executes an operation in a series of steps in cooperation with the test state machine. When activated, the co-processing state machine starts when the test state machine assumed a predetermined test state and subsequently it steps along with the test state machine starting for a number of clock cycles and makes use of transport through the scan chain and input/output from the scan chain that are controlled by the test state machine as it steps along with the co-processor state machine.

Thus, a very simple co-processor state machine can be used, which needs to provide only a predetermined series of signals. It does not need to handle or transport the information: it only has to supply control signals when the information has been handled under control of the test state machine. It does not need to execute a loop for handling successive words of information, because it is started each time as a by-product of state flow of the test state machine. By using the test clock to control the state machine, no complex clock interfacing is needed for the transfer of data from the scan chain.

In an embodiment the co-processor state machine is arranged to program an item of information from the scan chain into a non-volatile memory each time it is started. By using a co-processor state machine, predetermined programming signals can be applied to the non-volatile memory from the co-processor state machine, so that these some or all of these programming signals need not be transported via the scan chain. Typically three or more different successive states are used for programming the memory. A CPU is not needed because the supply of the programmed information and looping to program different items of information is controlled by the states assumed by the test state machine. The co-processor state machine is independent of the presence of such a CPU and other functions in the apparatus. It does not depend on the availability of normal clock signals (other than the test clock signal) during programming, or on clock domain interfaces if the apparatus uses more than one clock domain. As a result the co-processor state machine needs to be designed only once for many different apparatuses. It can be implemented in dedicated hardware that does not need to be bootstrapped before programming can commence.

Preferably, the co-processor state machine can be switched between different modes, different modes enabling or disabling programming respectively, and other different modes enabling programming with signals as needed for different types of non-volatile memory for example. Preferably switching to different ones of these modes is controlled with instructions passed through the scan chain.

These and other objects and advantageous aspects shall be described in more detail using the following figures

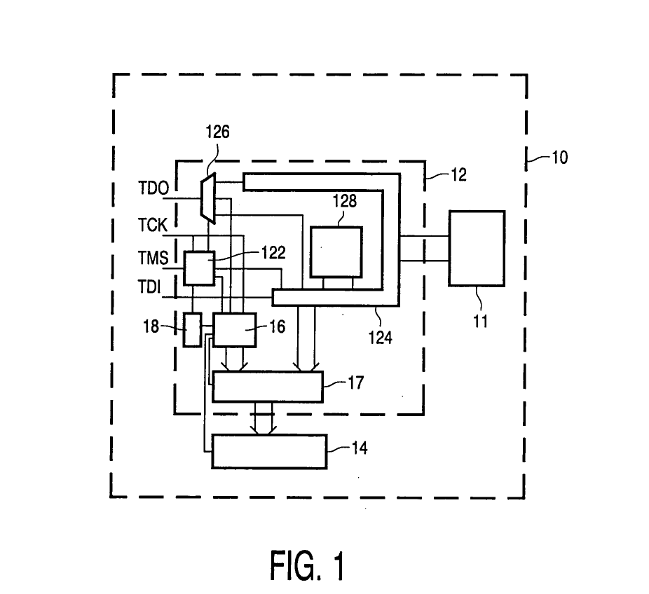

FIG. 1 shows an apparatus

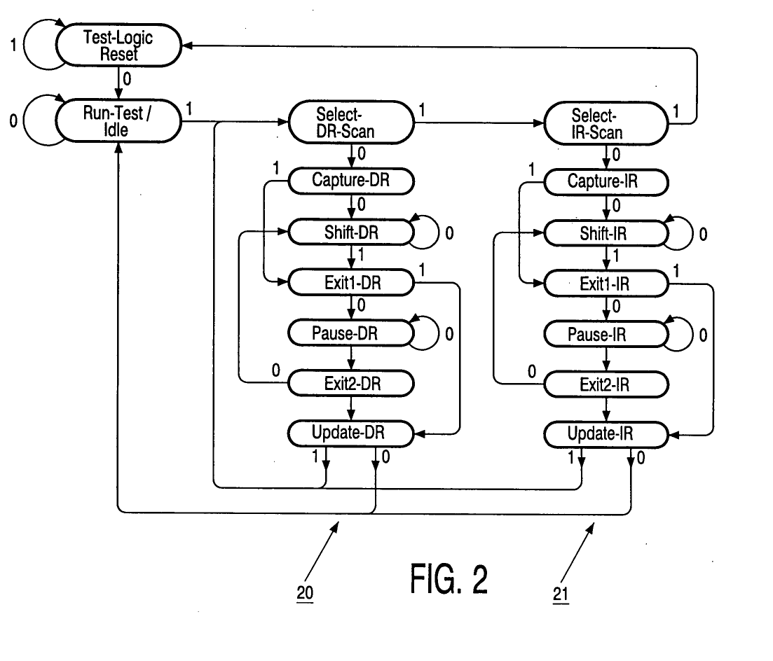

FIG. 2 shows a state diagram of a test interface

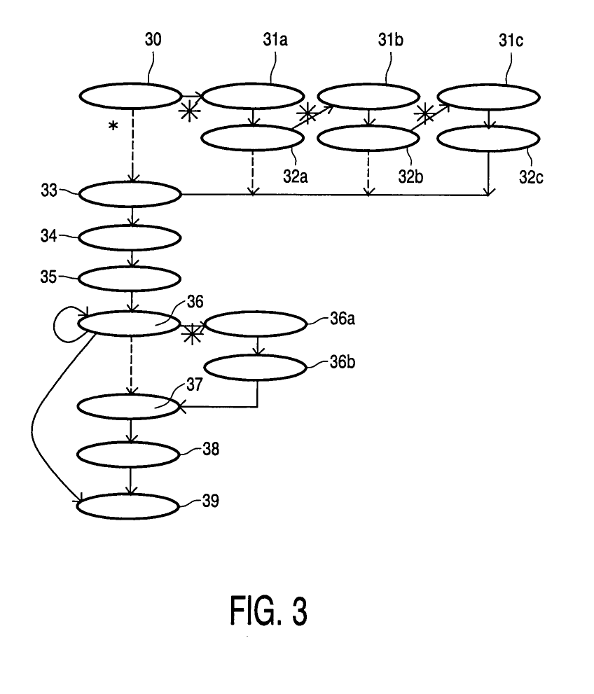

FIG. 3 shows a state diagram of a programming interface

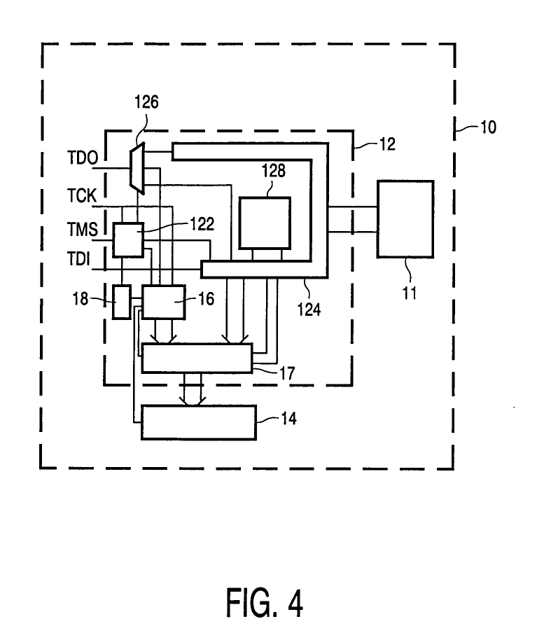

FIG. 4 shows a further apparatus.

FIG. 1 shows an apparatus 10 that contains a number of integrated circuits 11, 12, 14. A first one of the integrated circuits 12 has a test interface comprising a test controller 122, a scan chain 124, and an output selector 126. The scan chain 124 has a serial input, a serial output and parallel inputs/outputs. The other integrated circuits 11, 14 are coupled to the first one of the integrated circuits 12 via the parallel inputs and outputs of the scan chain 124. One of these other integrated circuits 14 is a flash memory.

The scan chain 124 is a conventional boundary scan chain. It contains a shift register (not shown) and update registers (not shown). Under control of the test controller 122 the scan chain shifts data through the shift register from its serial input to its serial output, loads data from the parallel input/outputs into the shift register, outputs data from the shift register to the update register and from there to the parallel inputs/outputs or passes data between internal circuits and external pins of the integrated circuit 12.

The integrated circuit 12 with the test interface contains a functional circuit 128 that is coupled to parallel inputs and outputs of the scan chain 124, a multiplexer 17, a programming control register 18 and a flash controller 16. The parallel outputs of the scan chain 124 and the flash controller 16 are coupled to the flash memory 14 via multiplexer 17. Flash controller 16 has control outputs coupled to control inputs of the multiplexer 17 and the flash memory 14. The serial input of the scan chain is coupled to a test data input (TDI) of the test interface and the serial output is coupled to a test data output (TDO) of the test interface, the latter via the output selector 126. The output selector 126 has further inputs coupled to an output of the flash controller 16 and an intermediate output of the scan chain 124. The test controller 122 has control inputs TCK, TMS and TRST coupled to the test interface and outputs coupled to the scan chain 124, the output selector 126, the programming control register 18 and the flash controller 16. The programming control register 18 is coupled to a control input of flash controller 16.

In operation, the apparatus 10 can be used in a normal mode and a test mode. In the normal mode the scan chain 124 is transparent and the functional circuit 128, the flash memory 14 and the integrated circuit 11 communicate directly with each other. In the test mode, the scan chain is not transparent and data is supplied to these circuits 128, 11, 14 through the scan chain 124 and received from them through the scan chain 124. With respect to normal test operations the apparatus operates for example according to the JTAG test standard (IEEE standard 1149).

FIG. 2 shows a state diagram that describes test operation of the test controller 122 in standard test operation. The state diagram shows a number of states that the test controller can assume. The states are connected by arrows. Each arrow is labeled with a value 0 or 1 of the signal TMS of the test interface. When the test controller 122 is in a specific state and the test clock signal TCK has a rising edge, the test controller 122 makes a transition to the next state dependent on the value of the TMS signal, as indicated in FIG. 2. Thus, the test controller steps through a selectable series of states.

The state machine may be implemented for example using a state register (not shown) and a memory (not shown) with locations that correspond to respective states. However, the invention is not limited to this implementation. Other implementations, such as dedicated hardwired circuitry that can assume the different states may also be used. Generally speaking, a state machine is any circuit that is capable of assuming different states successively, in which the circuitry defines at least partially which states will follow one another.

In the implementation with a state register and a memory the state register stores an address of the location that corresponds to a current state. In each location signal values are stored of signal values that will be applied to various circuits when the state machine is in the corresponding state. The location also contains information indicating the address of the locations that correspond to the states that can be reached from the current state. Under control of the TMS signal, one of these addresses is selected and loaded into the state register on the rising edge of the TCK signal.

In FIG. 2 a first column 20 of states contains states involved in reading and writing of data. A second column of states 21 contains states involved in reading instructions. To read or write data, for example, a signal value 0 is first applied to the TMS input in order to cause the test controller to make a transition from the “Test-Logic-Reset” state to the “Run-Test-Idle” state. Then a logic one value is applied to TMS to reach the “Select-DR-Scan” state and subsequently a logic 0 value is applied to reach the “Capture-DR” state. In this state, the test controller applies a control signal to the scan chain 124 that makes it capture data from its parallel inputs into the shift register of the scan chain. From this state the test controller 122 makes a transition to the “shift DR” state or the “Exitl-DR” state dependent on the value of TMS. In the shift DR state, the test controller 122 supplies a signal to the scan chain 124 to shift data though the shift register. The test controller 122 repeats this for each clock cycle on TCK as long as it remains in the shift DR state. Under control of TMS the test controller 122 will leave the Shift DR state for the Exit1 DR state. From there it makes a transition to the Pause DR state or the Update DR state, dependent on the value of TMS.

In the update DR state the test controller 122 causes scan chain 124 transfer data from the shift register into the update register for output to the pins of the integrated circuit 12. From the update DR state the test controller 122 transits back to the Run test idle state or the select DR scan state. The test controller can stay in the pause DR state for a number of cycles or make a transition to the exit2 DR state, from where it can make a transition to the Update DR state or back to the shift DR state.

Thus, by applying a specific sequence of TMS signal values to the TMS input of the test interface one can make test controller 122 cause scan chain 124 to load and output data into and from the shift register, to shift data through the shift register during a number of cycles, to pause and to output data to the serial output etc. Similarly, one can make the test controller 122 cause scan chain 124 to transport and apply instructions through the shift register, by applying TMS values that let test controller 122 reach the states in the right column 22 of the state diagram of FIG. 2. Such instructions include for example an instruction to route data from the scan chain from an input of the output selector 126 to TDO output, so that data from the TDI input is routed to the TDO output through the entire scan chain. Other examples are an instruction to route data from the TDI input to the TDO output bypassing the scan chain, an instruction to select whether test signals are exchanged between the scan chain 124 and the internal functional circuit 16 or the external pins of the integrated circuit 12.

In an embodiment of the invention, state flow of the state machine is also used to program non-volatile memory 14. Programming a flash memory, for example, involves a series of steps which are executed under control of the state machine in test controller 122.

FIG. 3 shows an example of a state diagram of states involved in programming a non-volatile memory. The state diagram is shown generically, for a number of different types of non-volatile memories. The state diagram will be discussed for one type of nonvolatile memory first. A number of state transitions that are not used for this type of non-volatile memory, but that are used for other types of non-volatile memory are shown as dashed lines. The state transitions that they replace in this case are marked with a “*”.

The state diagram contains a starting state 30. From this starting state 30 there is a transition to a first primary command state 31a. In the first primary command state 31a flash controller outputs a first command to flash memory 14 via scan chain 124. The first command comprises for example a write enable signal in combination with predetermined address and data that are generated by flash controller 16 (in an example the data and address are the logical inverse of one another). In this case, flash controller 16 controls multiplexer 17 to output this address and data from flash controller 16. From the first primary command state 31a, there is a transition to a first secondary command state 32a, from which there is a transition to a second primary command state 31b. In second primary command state 31b flash controller outputs a second command to flash memory 14 via scan chain 124. The second command comprises for example a write enable signal in combination with predetermined address and data that are generated by flash controller 16 (for a typical flash memory, the address and data in the second command are the inverse of the address and data in the first command respectively). The first secondary command state 32a serves to separate output of the first and second command to flash memory 14. From the second primary command state 31b there is a transition to a second secondary command state 32b, from there to a third primary command state 31c, from there to a third secondary command state 32c. From the third secondary command state 32c there is a transition to a primary programming state 33. The primary command states 31a-c have similar functions and the secondary command states 32a-c have similar functions.

In the primary programming state the flash controller 16 causes address and data bits from the shift register in scan chain 124 to be applied to flash memory 14. For this purpose, flash controller 16 controls multiplexer 17 to pass address and data bits from the scan chin 124. The data bits contain the information that is to be programmed into the flash memory 14 and the address bits specify the address where this information is to be stored in flash memory 14. (In an alternative embodiment, the address bits are supplied from a counter (not shown) in flash controller 16. The counter is incremented each time after an address has been applied). From the primary programming state 33 there is a transition to a secondary programming state 34. This state serves to separate the signals applied to the memory in the primary programming state from subsequent signals. From the secondary programming state 34 there is a transition to a primary polling state 35.

In the polling state 35 flash controller 16 receives back information from flash memory 14 to indicate whether the programming of the information received in the primary program step 33 has been completed. If not, the transition is made to remain in the primary polling state 35. Once programming has been completed a transition is made to a secondary polling state 36. From there a transition is made to a primary clear state 36a, in which flash controller 16 outputs a signal to clear a status of flash memory 14. From primary clear state 36a there is a transition to secondary clear state 36a, and from there to a primary reset state 37. In the reset state 37 flash controller 16 applies a reset signal to flash memory 14. From the primary reset state 37 there is a transition to a secondary rest state 38 and from there to a terminal state 39.

Now referring back to FIG. 1, the flash controller 16 is arranged as a flash programming state machine to implement the states and transitions shown in FIG. 3. Upon an instruction received in a conventional way from scan chain 124, a code is loaded from the scan chain into the control register 18. When the code has a first value it disables flash controller 16, when the code has a second value, it enables flash controller 18. When the state machine of the test controller 122 assumes a predefined state and the flash controller 16 is enabled, the flash controller assumes the start state 30 and starts making transitions. The flash controller state machine makes the transitions of the state diagram of FIG. 3 in step with transitions of test controller 122 through the state diagram of FIG. 2. On each rising edge of TCK the flash controller state machine makes a transition. Thus, the flash controller state machine may make transitions between different states even when the test controller makes transitions which do not result in a state change.

The flash programming state machine is started for example when the test controller assumes the “Update DR” state and the flash programming state machine has been enabled by an instruction. At this time data and (optionally) address for writing to the flash memory is loaded into the update register of the scan chain 124. After a number of transitions between states 31a-c, 32a-c in which it applies predetermined command data to the flash memory 14, the flash controller 16 will reach the primary program state 33 in which it causes this data and address to be applied to the flash memory 14. The state assumed by the state machine of the test controller at this time depends on the TMS values that are applied to the test interface. Typically the test controller 122 will be in the “Shift-DR” state by this time.

The flash controller 16 will assume the primary polling state 35 for a number cycles during this time. Finally, when the flash controller 16 has reached the terminal state 39, test controller 122 will still be in some state in the data branch 20, preceding the next “Update DR” state. Each time the test controller 122 reaches the “Update-DR” state, the flash controller is started anew.

FIG. 3 shows an “error” transition from the primary polling state 36 to the terminal state 39. Flash controller 16 takes this transition when the polling state “times out” (is assumed more than a specified number of successive clock cycles, e.g. at least 3 clock cycles). In this case it is assumed that an error has occurred in the flash memory 14. Thus, it is ensured that the flash controller 16 will not “hang” indefinitely other than in the terminal state, so that a well defined start of programming occurs when the test controller 122 again reaches the update-DR state.

Of course any other state of the state diagram of FIG. 2 may be used to start the start state 30. Using the “Update-DR” state, however, has the advantage that it is strictly synchronized with output of new data and address information. This simplifies design of the flash controller 16.

FIG. 4 shows an embodiment of the apparatus in which an output of the flash memory 14 is coupled to the scan chain 124. In this embodiment, one or more of the states of flash controller 16 involve generating signals that cause status information derived from the flash memory 14 to be applied to scan chain. Under control of the states of test controller 122 this information is loaded into the shift register of the scan chain and shifted out. In another embodiment, the one or more states of the flash controller 16 provide for reading back of the data written into the flash memory 14, comparing read-back data with the written data and applying a result of the comparison to the scan chain 124. Thus, the output TDO of the scan chain may be used to verify success of the flash memory 14 programming operation. Alternatively, the circuit may include hardware between the memory 14 and the scan chain 124 to compute error check information from the data that is read back from the memory 14, for example a linear feed-back shift register (not shown). In a state after giving control signals to read back the data, flash controller sends control signals to this hardware to update the error check information (which may be a syndrome, a CRC etc.) in an error check register. Using conventional boundary scan techniques the error check register is loaded into the scan chain so that it can be read out from the integrated circuit.

FIG. 3 shows transitions for programming a specific type of non-volatile memory. Transitions for programming other types of non-volatile memory are also shown. Of course further transitions and states other than those shown are also possible. In an embodiment, the control register is able to contain different codes that select which of the transitions will be active. The control register may be set in a conventional way from the scan chain 124. Thus, state sequencing of the flash controller 16 is adapted to the specific type of flash memory 14 that is connected to the integrated circuit 12 in the apparatus 10.

As shown the state machine in the test controller 122 and the flash controller 16 select transitions independently, in the sense that the one can make a transition between different states when the other makes a transition without changing state and vice versa. Alternatively the two state machines operate fully synchronously, each making transistions only when the other makes transitions. In this case modified state diagrams apply, for example the state diagram of FIG. 2 with states that affect both the scan chain and flash programming. To allow for combined control of the scan chain and possible delays during flash programming, this requires additional states in comparison with the state diagram. For example successive “Run test idle states” may be included, which have identical effect on testing, but different effect on flash programming. These states are assumed only when the integrated circuit 12 is enabled to program the memory. If the integrated circuit 12 has to satisfy a test standard with standard state diagrams such additional states are undesirable, because they may compromise compatibility with the standard.

By now it will be appreciated that that the flash control unit 16 acts as a co-processor for the test controller 122, stepping through a series of states in parallel with state transitions in the test controller 122. By stepping through these states the flash controller 16 performs a co-processing operation, in particular programming information into the flash memory 14, which the standardized test controller 122 is not capable of performing. The flash control unit 16 is started by the test controller 122 when the test controller assumes a specific state and its operation is thus synchronized to the test controller 122, so that it can use data from the scan chain 124 as it is supplied under control of the test controller. In this way, the flash controller does not need to have its own data loading instructions.

It will be understood that this principle can be applied more generally to other operations than programming a non-volatile memory 14, when a number of successive steps have to be performed to execute some operation that uses data from the scan chain 124 or produces results for transport by that scan chain 124.

By including an additional state machine to the test state machine the function of a co-processor state machine is realized. The test state machine and this co-processor state machine operate in step: they make state transitions under control of the same test clock signal. The co-processor state machine 16 successively assumes a series of states every time after it is started. The co-processor state machine is started in a start state 30 of the series when the test state machine assumes a predefined state and the co-processing state machine has been enabled, for example by an instruction from the scan chain. In successive co-processor states of the series the co-processing state machine successively outputs signals that control execution of an operation which uses information that has been output from the scan chain and/or produces a result that is read into the scan chain. The output of this information and/or reading of the result and the transport of the information and/or result is under control of signals output by the test state machine in successive test states. The clock cycles of TCK in which the test state machine assumes these test states are coordinated with the clock cycles in which the co-processor state machine assumes the co-processing states that use or produce the information or results, because the co-processor state machine is started when the test state machine assumes the predetermined state.

1. An apparatus comprising
a boundary scan unit, comprising a clock input for receiving a clock signal, a shift register and a test state machine capable of assuming respective test states successively in successive cycles of the clock signal, the test state machine having outputs that control transport of data through the shift register and between the shift register and a circuit under test, dependent on which of the test states the test state machine has assumed;
a co-processor state machine, capable of assuming respective co-processor states successively in successive cycles of the clock signal, the co-processor state machine being arranged to start making transitions from a start state, when enabled, in response to assumption of a predetermined one of the test states by the test state machine, the co-processor states assumed by the co-processor state machine following the start state controlling successive steps of an operation that uses data output from the scan chain under control of the test state machine and/or produce results read into the scan chain under control of the test state machine following the predetermined state.

2. A apparatus according to claim 1, comprising a co-processor control register, that is writeable from the scan chain, the control register being coupled to the co-processor state machine to select between enabling and disabling the co-processor state machine to start making transitions.

3. An apparatus according to claim 1, comprising a non-volatile memory, the co-processor state machine being arranged to supply successive control signals for programming the non-volatile memory in respective ones of the co-processor states that the co-processor state machine assumes in succession when started, the data read from the scan chain being applied to the non-volatile memory to program the data into the non-volatile memory under control of the control signals.

4. A apparatus according to claim 1, comprising a co-processor control register, that is writeable from the scan chain, the control register being coupled to the co-processor state machine, the control register being capable of storing a code that distinguishes different types of non-volatile memory that need different sequences of programming controlling signals, the control register selectively enabling one of a number of different possible sequences of co-processor states that the co-processor state machine will follow, as appropriate for programming the different types of non-volatile memory.

5. An apparatus according to claim 3, the co-processor states comprising read back states for supplying signals to read back information from the nonvolatile memory after programming the data and to supply a result derived from said read back to the shift register for reading into the scan chain.

6. An apparatus according to claim 5, the apparatus comprising a circuit for computing an error check value, the co-processor states comprising a state for causing the circuit for computing the error check value to update the error check value using the information read back from the non-volatile memory, the circuit for computing the error check value being coupled to the scan chain so-as to allow reading the error check value into the scan chain.

7. An apparatus according to claim 3, the co-processor states comprising a poll state, the co-processing state machine being arranged to detect when the non-volatile memory has completed programming of an item of data, and to loop to the poll state, independent of state transitions taken by the test state machine, until co-processing state machine detects that programming has been completed, the co-processing state machine assuming a further state from the poll state when programming is completed.

8. An apparatus according to claim 7, the co-processing state machine being arranged to exit from the poll state to a terminal state when the co-processing state machine detects that the co-processing state machine has looped to the poll state more than a predetermined number of times.

9. An integrated circuit comprising
a boundary scan unit, comprising a clock input for receiving a clock signal, a shift register and a test state machine capable of assuming respective test states successively in successive cycles of the clock signal, the test state machine having outputs that control transport of test data through the shift register and between the shift register and a circuit under test, dependent on which of the test states the test state machine has assumed;
connection pins suitable for connecting a non-volatile memory;
a co-processor state machine, capable of assuming respective co-processor states, the co-processor state machine starting to make transitions from a start state, when enabled, in response to assumption of a predetermined one of the test states by the test state machine, the co-processor states assumed by the co-processor state machine following the start state supplying of successive control signals for programming data transported from the scan chain under control of the test state machine to the connection pins for programming the non-volatile memory in successive cycles of the clock signal following the predetermined state.

10. A method of programming a non-volatile memory, the method comprising
entering information items that have to be programmed into the non-volatile memory into a boundary scan chain;
using a standard test state machine to control transport of the information items through the boundary scan chain and output of the information items from a parallel output of the boundary scan chain, the information items being output successively, each following a respective assumption of a same predetermined state by the test machine;
using a co-processor state machine to control programming of the information, the co-processor state machine being started from a start state repeatedly, each time by guiding the test state machine through the predetermined state, the co-processor state machine running in step with the test state machine from said predetermined state, states following the start state being arranged to make the non-volatile memory program the information item output from the boundary scan chain following the predetermined step.
